(19) United States
(12) Patent Application Publication
(10) Pub. No.: US 2010/0147383 A1
(43) Pub. Date: Jun. 17, 2010

(54) METHOD AND APPARATUS FOR LASER-PROCESSING A SEMICONDUCTOR PHOTOVOLTAIC APPARATUS

(76) Inventors: James E. Carey, Waltham, MA (US); Martin U. Pralle, Wayland, MA (US)

Correspondence Address: PEPPER HAMILTON LLP, ONE MELLON CENTER, 50TH FLOOR, 500 GRANT STREET, PITTSBURGH, PA, 15219, US

(21) Appl. No.: 12/336,722

(22) Filed: Dec. 17, 2008

(51) Int. Cl. H01L 21/20; H01L 31/0256; H01L 31/036; H01L 21/04

(52) U.S. Cl. 136/261; 438/57; 438/478; 257/E31.003; 257/E21.09

(57) ABSTRACT

The present disclosure is directed to a method for automated manufacturing thin film solar cells including a laser processed layer. The method includes depositing a plurality of substantially planar layers in proximity with one another, including at least a first semiconductor layer, feeding the plurality of layers through a plurality of processing steps, irradiating at least a portion of a layer of the plurality of layers with a source of laser radiation, and using a control computer to control at least one of the acts of feeding and irradiating in the automated manufacture of the thin film solar cells.

### I. TECHNICAL FIELD

The present disclosure relates to the manufacture of thin film photovoltaic cells.

### Il. RELATED APPLICATIONS

N/A

### III. BACKGROUND

The advantages of thin film solar cells over “thick” cells include reduced material cost, large area and complete module processing, and the ability to be fabricated on flexible and transparent substrates. However, to date, most thin-film technologies have lower efficiencies as compared to thick substrates. The efficiency loss is mainly attributed to absorption losses and crystalline defects. Reduced cost but lower efficiency becomes a hurdle to competing in large-scale power generation applications where there are surface area constraints and installation costs dominate the overall cost structure.

The most common material groups used in thin-film solar cells are silicon (amorphous and polycrystalline), Copper indium diselenide (CIS and CIGS if gallium is included), and cadmium telluride (CdTe). For exemplary discussion we will discuss the background of thin-film silicon solar cells, but the advantages of laser processing described herein can be extended to other thin-film material systems.

Amorphous silicon and microcrystalline thin films are typically grown or deposited using chemical vapor deposition on a transparent substrate such as glass or a flexible plastic. The semiconductor component of silicon thin film solar cells is typically a few microns in thickness, as compared to hundreds of microns for thick solar cells. The savings in raw material provides an economic advantage and these types of thin film devices save on raw silicon material usage over traditional thick cells because they have much higher absorption efficiency. In addition, the reduction in processing steps and the ability to make entire solar cell modules on one substrate offer significant manufacturing and cost advantages. However, thin-films can suffer from needing enough thickness to absorb sufficient light, and reduced carrier collection efficiency as the semiconductor layers get thicker. Mobilities are often lower in thin-film devices, so a strong field and a short travel distance for photocarriers improves efficiency. In addition, growing a thicker film takes more manufacturing time, more material, adds stress, and at some thickness becomes impractical.

In the case of amorphous silicon, the band gap is such that light beyond 750 nm is not absorbed (as compared to 100 nm for thick crystalline silicon). The solar spectrum has more than 50% of its energy in wavelengths longer than 750 nm. Therefore a large portion of the solar spectrum may not be converted to electricity in thin-film amorphous solar cells.

### IV. SUMMARY

The following disclosure provides methods, apparatus, and articles of manufacture for obtaining improved and novel thin-film solar cells. Embodiments hereof provide a method of using short pulse laser processing to create an absorbing layer within a thin film silicon solar cell that enhances the effectiveness of solar cells, especially in their long wavelength light conversion efficiency.

The combination of high quantum efficiency thin film silicon for short wavelengths and the high quantum efficiency of laser processed silicon for longer wavelengths enables a new type of solar cell that has low material costs and improved quantum efficiency performance. In some instances, the present cells' efficiency is on par with thick crystalline solar cells. In addition, the present solar cell may utilize only silicon as a semiconductor material in some embodiments, and thereby reduces cost compared to traditional thin film cell types such as cadmium telluride and copper indium gallium diselenide. Furthermore, the present embodiments may not require the use of toxic materials in their construction.

Embodiments of the present single-material, combination solar cell take advantage of the strengths of current thin-film silicon solar cells and increase efficiency especially at longer wavelengths, by using high quantum efficiency laser processed silicon as an absorbing semiconductor layer, i.e. a backstop for light.

In general, in an aspect, an article of manufacture may be provided. The article comprising a substrate layer, a thin film solar cell disposed on the substrate layer, said thin film solar cell comprising a laser-treated portion, the laser treated-portion being formed by application of laser radiation in an automated process.

Implementations of the article may include one or more of the following features. The substrate layer is flexible. The laser radiation comprises pulsed laser radiation. The application of the laser is performed in an inert environment. The application of the laser may be performed in a process environment that contains a desired dopant chemical species. The thin film solar cell comprises an intrinsic silicon layer. The application of laser radiation is applied to the intrinsic layer. The application of laser radiation in an automated process is controlled by a computer.

Implementations of the article may also include one or more of the following features. The thin film solar cell is a solar cell with quantum efficiency greater than 50% for light wavelengths longer than 800 nanometers and the thin film solar cell has a material thickness less than 20 microns. The thin film solar cell is a solar cell with quantum efficiency greater than 80% for light wavelengths longer than 900 nanometers and the thin film solar cell has a material thickness less than 20 microns. The application of the pulsed laser radiation further includes annealing the laser-treated portion at an anneal temperature greater than 1075 K and less than 1475 K, and application of the pulsed laser radiation is performed with less than 100 laser shots per unit area and a laser fluence greater than 1 kJ/m² and less than 6 kJ/m². The laser-treated portion includes resultant surface structures from the laser treatment that are less than 10 microns high from the laser-treated portion surface. The laser-treated portion includes resultant surface strictures from the laser treatment that are less than 5 microns high from the laser-treated portion surface. The laser-treated portion includes resultant surface structures from the laser treatment that are less than 3 microns high from the laser-treated portion surface.

In general, in another aspect, a method for automated manufacturing of thin film solar cells including a laser processed layer may be provided. The method comprising depositing a plurality of substantially planar layers in proximity with one another, including at least a first semiconductor layer, feeding said plurality of layers through a plurality of processing steps, irradiating at least a portion of a layer of said plurality of layers with a source of laser radiation, and using a control computer to control at least one of said acts of feeding and irradiating in said automated manufacture of said thin film solar cells.

Implementations of the method may include one or more of the following features. The depositing of a plurality of substantially planar layers includes depositing a second semiconductor layer, the second semiconductor layer being deposited subsequent to the irradiating of the first semiconductor layer. The depositing of a plurality of substantially planar layers includes depositing a third semiconductor layer, the third semiconductor layer being deposited subsequent to the deposition of the second semiconductor layer. The depositing of a plurality of substantially planar layers includes depositing a second semiconductor layer, and irradiating said second semiconductor layer with said pulsed source of radiation. The depositing of a plurality of substantially planar layers includes depositing a second semiconductor layer, and depositing a third semiconductor layer, and the irradiating includes irradiating the third semiconductor layer with a pulsed source of radiation. The irradiation of the third semiconductor layer is performed in an inert gas environment. The method further comprising providing a flexible substrate for depositing said plurality of substantially planar layers onto the flexible substrate using a roll-to-roll process. The irradiating comprises irradiating with femtosecond pulsed laser radiation. The irradiation of a semiconductor layer is performed in a gas environment that contains a desired dopant chemical species. The method further comprising providing a substantially transparent substrate for depositing a plurality of substantially planar layers onto in an automated process.

Implementations of the method may also include one or more of the following features. The automated manufacture of said thin film solar cells produces a solar cell with quantum efficiency greater than 50% for light wavelengths longer than 800 nanometers and the thin film solar cell has a material thickness less than 20 microns. The automated manufacture of said thin film solar cells produces a solar cell with quantum efficiency greater than 80% for light wavelengths longer than 900 nanometers and the thin film solar cell has a material thickness less than 20 microns. The irradiation of the at least a portion of a layer further includes annealing the treated portion at an anneal temperature greater than 1075 K and less than 1475 K, and application of the radiation is performed with a pulsed laser with less than 100 laser shots per unit area and a laser fluence greater than 1 kJ/m² and less than 6 kJ/m². The radiation treated portion includes resultant surface structures from the irradiation that are less than 10 microns high from the treated portion surface. The radiation treated portion includes resultant surface structures from the irradiation that are less than 5 microns high from the treated portion surface. The radiation treated portion includes resultant surface structures from the irradiation that are less than 3 microns high from the treated portion surface.

In general, in another aspect, an article of manufacture may be provided. The article comprising a substrate layer, and a thin film solar cell disposed on the substrate layer, said thin film solar cell comprising a laser-treated portion, the laser treated-portion being formed by application of laser radiation, wherein the thin film solar cell comprises a solar cell with quantum efficiency greater thin 80% for light wavelengths longer than 900 nanometers and the thin film solar cell has a material thickness less than 20 microns.

Implementations of the article may include one or more of the following features. The quantum efficiency is in the range of 80% to 90%. The quantum efficiency is greater than 90%. The light wavelengths are in the range of 900 to 1100 nanometers. The light wavelengths are in the range of 1100 to 2500 nanometers. The laser-treated portion has a material thickness less than 1 micron.

Specific examples of applications of the present methods and apparatus include thin-film photovoltaic power generation.

Other uses for the methods and apparatus given herein can be appreciated by those skilled in the art upon comprehending the present disclosure.

### V. BRIEF DESCRIPTION OF THE DRAWINGS

For a fuller understanding of the nature and advantages of the present invention, reference is being made to the following detailed description of preferred embodiments and in connection with the accompanying drawings, in which:

FIG. 1 illustrates an exemplary cross section of a thin film solar cell;

FIG. 2 illustrates an exemplary manufacturing method of laser processed silicon according to some embodiments hereof;

FIG. 3 illustrates a flow chart of various stages of an exemplary process for manufacturing a thin film solar cell including a laser processed silicon layer;

FIG. 4 illustrates an exemplary system for manufacturing a thin film solar cell including a laser processed silicon layer;

FIG. 5 illustrates cross section of another exemplary thin film solar cell;

FIG. 6 illustrates a flow chart of various exemplary stages of a process for manufacturing a thin film solar cell including a laser processed silicon layer;

FIG. 7 illustrates another flow chart of various exemplary stages of a process for manufacturing a thin film solar cell including a laser processed silicon layer; and

FIG. 8 presents exemplary quantum efficiency data of three different types of solar cells, comparing the quantum efficiency of an amorphous silicon thin-film solar cell, a thick silicon solar cell, and a laser processed solar cell.

### V. DETAILED DESCRIPTION

As alluded to above, the present disclosure describes systems and articles of manufacture for providing thin-film laser processed photovoltaic solar cells and methods for making and using the same.

Some or all embodiments hereof include a portion comprising a semiconductor material, for example silicon, which is irradiated by a short pulse laser to create modified micro-structured surface morphology. The laser processing can be the same or similar to that described in U.S. Pat. No. 7,057,256. The laser-processed semiconductor is made to have advantageous light-absorbing properties. In some cases this type of material has been called “black silicon” due to its visually darkened appearance after the laser processing and because of its enhanced absorption of light and IR radiation compared to other forms of silicon. In some embodiments, a non-pulsed laser may be used to irradiate the semiconductor material. Those skilled in the art will appreciate that varying the laser wavelength from about 150 nm to about 20000 nm and varying the intensity from about 10 W/cm² to about 10⁹ W/cm² may achieve the same results as a pulsed laser system.

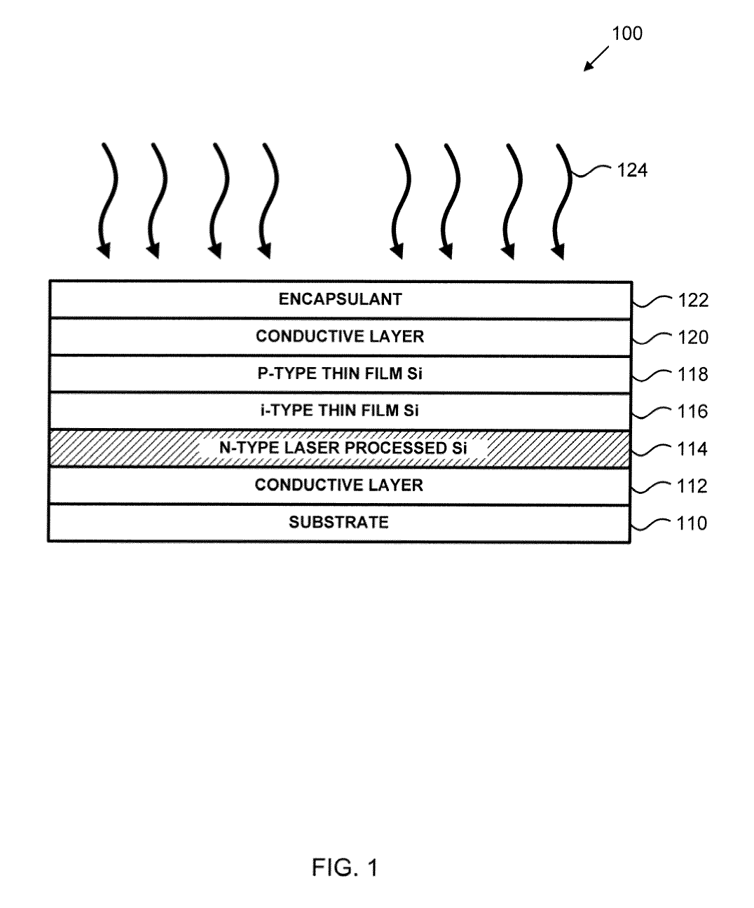

We now turn to a description of an exemplary thin film solar cell comprising a laser processed silicon layer. FIG. 1 illustrates a cross-section of an exemplary solar cell including a laser processed silicon layer. Although in the current embodiment silicon is semiconductor material that is laser irradiated, in other embodiments other semiconductor materials may compose the laser processed layer. The solar cell 100 includes a structural substrate layer 110, a conductive substrate layer 112, a n-type laser processed silicon layer 114, an i-type thin film silicon layer 116, a p-type thin film silicon layer 118, a transparent conductive layer 120, and an encapsulant layer 122.

The structural substrate layer 110 may be comprised of a suitable material such as a polymer or glass. The structural substrate layer 110 provides a base for the conductive substrate layer 112. The conductive substrate layer 112 may be of any suitable material such as aluminum or a transparent conductive layer. The n-type laser processed silicon layer 114 is in contact with the top surface of the conductive substrate layer 112, and may be of an appropriate thickness for a specific application, for example, between 10-5000 nanometers (nm) thick, particularly 100-500 nm. One micron equals 1000 nanometers, and thus in some embodiments, the laser-treated layer 114 may be less than one micron in thickness. An n-type semiconductor (n for negative) is obtained by carrying out a process of doping, that is, by adding an impurity of valence-five elements to a valence-four semiconductor in order to increase the number of free charge carriers (in this case negative). A p-type semiconductor (p for positive) is obtained by carrying out a process of doping wherein certain type of atoms are added to the semiconductor in order to increase the number of free charge carriers (in this case positive). An intrinsic (i-type) semiconductor is a substantially undoped semiconductor without significant dopant species present. In some embodiments, variations of n(−−), n(−), n(+), n(++), p(−−), p(+), p(+), or p(++) type semiconductor layers may be used. The minus and positive signs are indicators of the relative strength of the doping of the semiconductor material. Also, although in the current embodiment the laser processed silicon layer 114 is shown as n-type, in other embodiments it may be a p-type layer with the thin film silicon layer 118 being a n-type.

An i-type thin film silicon layer 116 of appropriate thickness, e.g. 0-5000 nm thick, particularly 500 to 1000 nm, resides on top of the n-type laser processed silicon layer 114. In some embodiments, an i-type silicon layer may not be present. The top surface of the i-type thin film silicon layer 116 is in contact with the p-type thin film silicon layer 118. The p-type thin film silicon layer 118 is an appropriate thickness for the application, such as 1-5000 nm thick, particularly 5 to 500 nm. In some embodiments, the total material thickness of the thin film solar cell may be less than 20 microns. A transparent conductive layer (such as indium tin oxide) 120, which may have antireflection or passivation such as silicon nitride or silicon dioxide, resides on top of and is in contact with the p-type thin film silicon layer 118. A transparent layer may be a layer that is substantially permissive of a range of light wavelengths. The encapsulant layer 122 is transparent and may be on top of the transparent conductive layer 120. Incident sunlight 124 strikes the top encapsulant layer 122 of the solar cell 100 and various wavelengths of the sunlight are absorbed by the layers 114, 116, and 118 of the solar cell 100.

The incident sunlight 124 includes relatively shorter wavelengths of light which are absorbed and converted into photocarriers within the p-type thin film silicon layer 118, or alternatively, the i-type thin film silicon layer 116. Longer wavelengths of incident sunlight 124 pass unabsorbed through the top two silicon layers 118, 116. The longer wavelengths of light may be absorbed in the n-type laser processed silicon layer 114. Thus, the n-type laser processed silicon layer 114 may perform as a back-stop for longer wavelength light.

In addition to absorption, high energy conversion requires that photocarriers are created and collected efficiently.

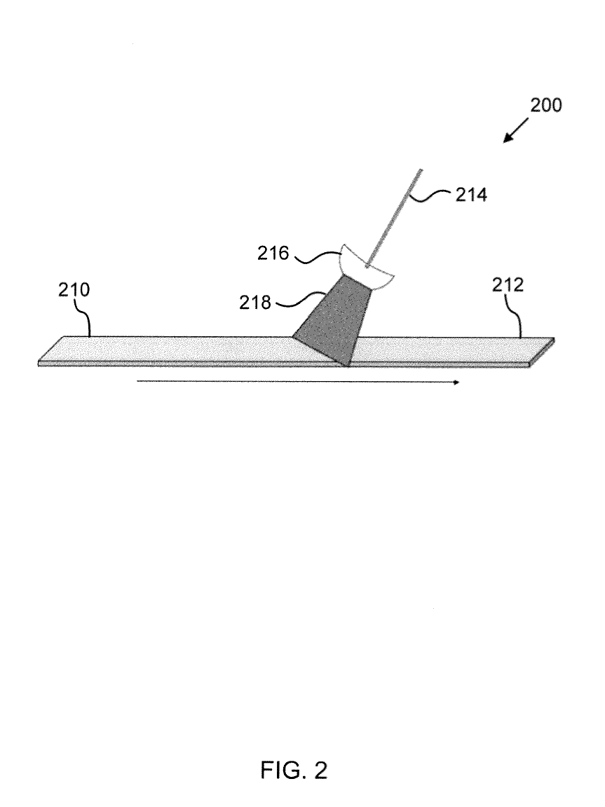

FIG. 2, with further reference to FIG. 1, illustrates an exemplary method and apparatus 200 for laser processing silicon in a thin film solar cell. The method and apparatus 200 includes providing a thin film layer of silicon deposited onto a supporting and conductive substrate 210, transporting laser processed thin film silicon on the conductive substrate away from the laser processing area 212, providing an appropriate laser beam or multiple laser beams 214, providing a cylindrical lens, beam splitter, scanning laser head or gantry system 216, and directing an appropriately sized laser beam or curtain of laser light 218 onto the silicon. Cylindrical lenses focus or expand light in one axis only. Cylindrical lenses can be used to focus light into a thin line from a collimated laser (beam). Thus a curtain of laser light can be formed by a laser beam passing through an appropriate shaped lens, beam spreader, or prism to form a line of laser light wide enough to cover the width of the silicon and substrate that travel through the curtain of laser light. The angle and focal length may be adjusted to provide the proper line or curtain thickness.

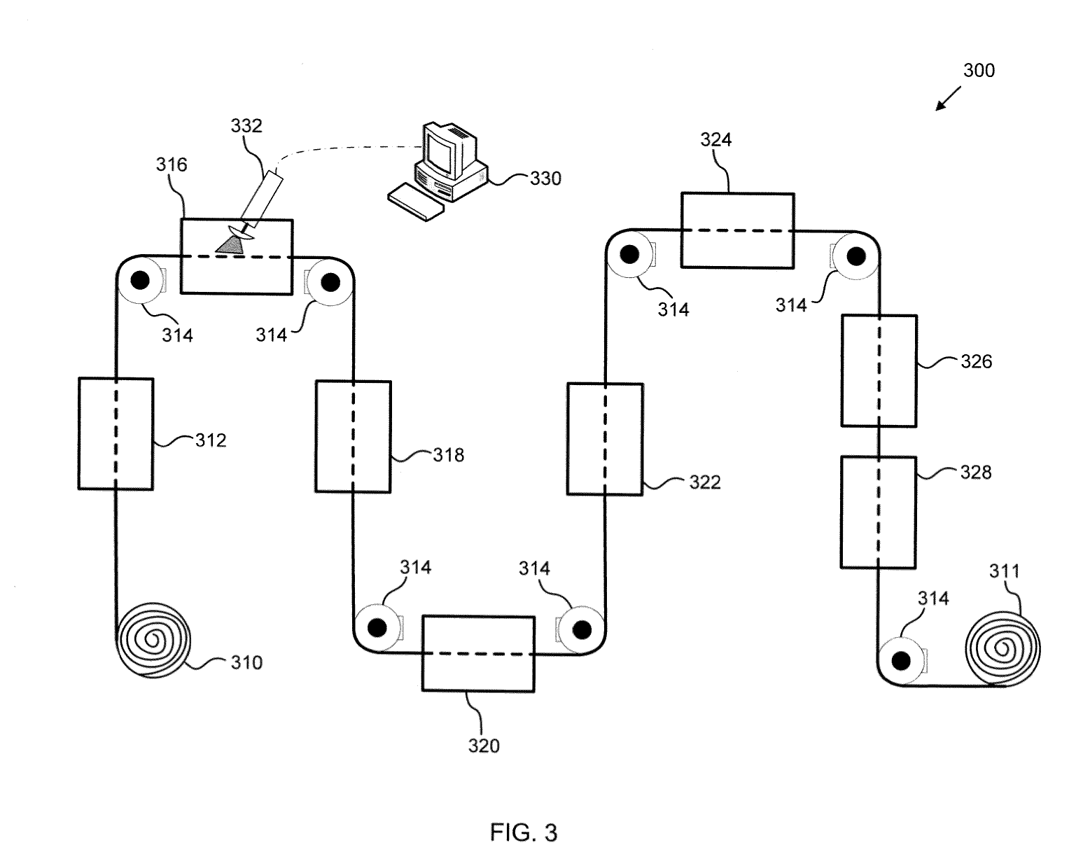

Referring to FIG. 3, with further reference to FIGS. 1 and 2, a laser processing method and system 300 may include appropriate equipment and processes to utilize a conveyor belt or a roll-to-roll process for laser processing the silicon for thin film solar cells. The laser processed thin-film photovoltaic manufacturing system 300 includes a flexible conductive substrate supply roll 310, a first silicon deposition module 312, a plurality of roller elements 314, a laser processing module 316, a laser assembly 332, a control computer 330, an annealing module 318, a second silicon deposition module 320, a third silicon deposition module 322, an antireflection and passivation deposition module 324, a transparent conducting layer deposition module 326, an encapsulant layer deposition module 328, and a flexible thin film photovoltaic take-up roll 311.

In this embodiment, a roll-to-roll processing technique is used to manufacture laser processed thin-film solar cells in a continuous manner on a continuous flexible substrate such as a conductive metal foil. A flexible substrate may be considered any substrate that is pliable, bendable, and can be wound onto a roll or spool without having to alter its material properties (e.g. heating). The system 300 includes the flexible conductive substrate supply roll 310, and the flexible thin film photovoltaic take-up roll 311, and the flexible substrate is directed from the supply roll 310 to the take-up roll 311 through a series of deposition and processing modules. The supply roll 310 may be a roll or spool of flexible substrate that can be inserted into the supply mechanism to feed flexible substrate to the system 300. The conductive metal foil substrate may be constructed from a suitable material such as aluminum, and may be configured as the back contact for the thin film solar cell.

The first silicon deposition module 312 may deposit a thin layer of intrinsic silicon onto the top-side of the flexible conductive substrate. The continuous web of flexible material may be advanced in a continuous or alternatively, a discontinuous manner to the next module of the system. The plurality of roller elements 314 may be disposed and configured to direct and guide the flexible material to the modules and through the manufacturing system 300.

The thin film layer of silicon deposited onto the supporting and conductive substrate may provided in an automated manner to the laser processing module 316 to be laser processed with femtosecond laser pulses in a gas environment that contains a desired dopant chemical species (which may include but is not limited to nitrogen, phosphorous, sulfur, etc). The laser processing can be accomplished by the laser assembly 332 via rastering the laser across the silicon surface or by using multiple laser beams. The laser assembly 332 may be operatively coupled to a control computer 330 which may control such variables as frequency, duration, fluence, and targeting of the laser assembly 332 as well as other system variables such as the linear speed of the flexible web/supply and take-up rolls 310, 311. An automated process may be considered a process which can be properly set up by a user to utilize control equipment such as a computer to control systems, machinery, and processes, thereby reducing the need for human intervention.

In one embodiment, laser processing of the silicon layer is performed with a curtain of laser light using one or more cylindrical lenses so that substantially all of the width of the web of flexible silicon is laser processed as it passes beneath the laser light in a roll to roll or conveyor belt process. In some embodiments, one laser beam may be focused to cover the width of the silicon layer and in other embodiments, multiple laser beams may be focused to cover the width of the silicon layer.

Subsequent to the laser processing of the silicon layer, an anneal process is carried out in the annealing module 318 to activate the dopant species implanted during laser processing. The anneal process within the annealing module 318 may be carried out through any means of annealing (i.e. Rapid thermal annealing, laser annealing, furnace annealing etc). At this point the laser processed silicon is a doped n-type or p-type layer depending on the dopant species used during laser processing.

The second silicon deposition module 320 may be configured and disposed to deposit an intrinsic layer of silicon of appropriate thickness on top of the laser processed silicon layer.

The third silicon deposition module 322 may be configured and disposed to deposit a thin layer of silicon on top of the intrinsic silicon layer. The silicon deposited by the third deposition module 322 may be an n-type or p-type layer depending on the dopant species used during the previous laser processing module 316. If the laser processed silicon layer is of the n-type, then the third silicon deposition module 322 deposits a p-type silicon layer. In contrast, if the laser processed silicon layer is of the p-type, then the third silicon deposition module 322 deposits an n-type silicon layer. The manufacturing system 300, may be configurable by a user for either a p-i-n, or a n-i-p solar cell architecture.

The antireflection and passivation deposition module 324 may be configured to deposit the antireflection and passivation layer on top of the n-type or p-type layer deposited by the previous third silicon deposition module 322.

The transparent conducting layer deposition module 326 may be configured to deposit a transparent conducting layer on top of the passivation layer with contact made to the n-type or p-type layer deposited by the third silicon deposition module 322.

The encapsulant layer deposition module 328 may be configured to deposit a transparent encapsulant on top of the transparent conductor.

The flexible thin film photovoltaic take-up roll 311 is configured to wind up the flexible solar cell assembly. The take-up roll 311 may be operatively coupled to the control computer 330 (not shown) and controlled to maintain a constant speed or torque setting in a continuous configuration or a specified motion profile in a discontinuous configuration.

The manufacturing system 300 can be configured and adapted for use with non-flexible substrate via removal of the supply and take-up rolls 310, 311 and the addition of a conveyor belt or similar transport mechanism for the non-flexible substrate. The system 300 may also be configured to operate in a batch process or discontinuous manner as opposed to the continuous manner described above. In addition, the manufacturing system 300 may be configured with a laser processing module 316 that operates within an inert gas ambient environment. Thus the first silicon deposition module 312 may deposit a thin layer of n-type or p-type silicon depending on the desired solar cell architecture.

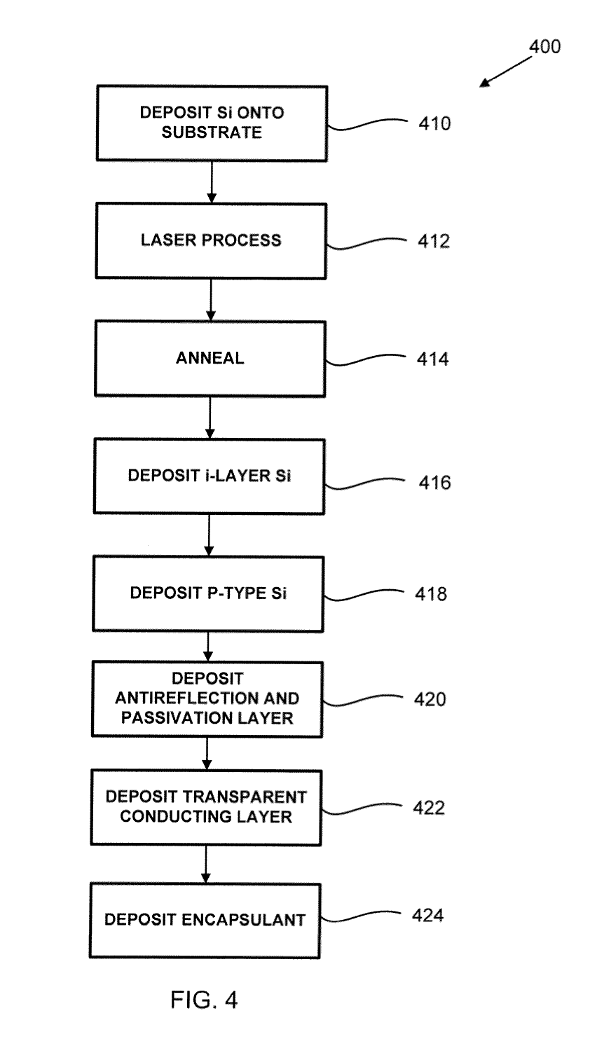

Referring to FIG. 4, with further reference to FIGS. 1-3, various stages of a process 400 are shown for manufacturing a thin film solar cell including a laser processed silicon layer. The process 400 includes providing a thin film layer of silicon deposited onto a conductive substrate 410, directing an appropriately sized laser beam or curtain of laser light onto the silicon in an automated manner as the silicon layer and conductive substrate pass from roll to roll or along a conveyor belt 412, annealing the processed silicon to activate the dopant species implanted during laser processing 414, depositing an intrinsic layer of silicon of appropriate thickness on top of the laser processed layer 416, depositing a p-doped silicon layer on top of the intrinsic silicon layer 418, depositing an antireflection and passivation layer on top of the p-doped layer 420, depositing a transparent conducting layer on top of the passivation layer with contact made to the p-doped layer of silicon 422, and depositing a transparent encapsulant layer on the transparent conductor 424.

The laser process stage 412 can be configured to operate in a gas environment that contains a desired dopant chemical species (which may include but is not limited to nitrogen, phosphorous, sulfur, etc). Depending on the dopant species used during laser processing, the laser processed silicon is a doped n-type or p-type layer. In the present embodiment, the laser process stage 412 generates a n-type silicon layer. The laser process stage may be operatively connected to a control computer which may control the various laser parameters during the processing stage 412.

The annealing stage 414 may be carried out through a plurality of means of annealing (including but not limited to rapid thermal annealing, laser annealing, and furnace annealing) or any combination thereof. The annealing stage 414 may be operatively connected to and controlled by a control computer.

Any one of or all of the various stages of the process 400 may be controlled by a control computer configured to monitor specific process variables and conditions and output appropriate control signals to the various stages of the process 400.

The intrinsic silicon layer deposition stage 416 may be configured to deposit an appropriate thickness of intrinsic silicon on top of the laser processed layer.

The p-type silicon layer deposition stage 418, may be configured to deposit a p-type doped silicon layer on top of the intrinsic silicon layer. Although the silicon layer deposited in this stage 418 is p-type in this embodiment, in other embodiments, the silicon layer deposited in this stage 418 may be of n-type doped silicon if the laser processed silicon layer in stage 412 is of p-type silicon.

The antireflection and passivation layer deposition stage 420, may be configured to deposit an antireflection and passivation layer on top of p-type silicon layer.

The transparent conducting layer deposition stage 422, may be configured to deposit a transparent conducting layer on top of the passivation layer with contact made to the p-type silicon layer deposited in stage 418.

The encapsulant deposition stage 424, may be configured to deposit a transparent encapsulant layer on top of the transparent conducting layer.

In another embodiment, a method and system for laser processing silicon in a thin film solar cell may include appropriate equipment and processes to utilize large scale chemical vapor deposition onto supporting glass substrates with transparent conducting layers. Thus, a thin layer of the appropriately doped silicon can be deposited onto a substrate, such as glass, and then moved along with conveyor belts for continued processing. In one embodiment, the thin layer of doped silicon is comprised of a layer of p-doped silicon in contact with the transparent conducting layer and an intrinsic silicon layer in contact with the p-doped silicon layer. In another embodiment, the thin layer of doped silicon is comprised of a layer of n-doped silicon in contact with the transparent conducting layer and an intrinsic silicon layer in contact with the n-doped silicon layer. The thin film intrinsic layer of silicon deposited onto n-doped or p-doped silicon which is on a supporting substrate. The substrate including the intrinsic layer may be provided in an automated process into a processing chamber to be laser processed with femtosecond laser pulses in a gas environment that contains a desired dopant chemical species (which may include but is not limited to nitrogen, arsenic, boron, phosphorous, sulfur, etc). In one embodiment, the desired dopant chemical species for the laser processed layer is incorporated during the chemical vapor deposition process. The laser processing can be accomplished by rastering the laser across the silicon surface or by using multiple laser beams. In one embodiment, laser processing of the silicon layer is performed with a curtain of laser light using one or more cylindrical lenses so that substantially all of the width of the silicon layer is laser processed as it passes beneath the laser light in a conveyor belt process. Following laser processing a conductive back contact may be deposited onto the laser processed layer. The conductive back contact can be constructed from a suitable material such as aluminum, and may be configured as the back contact for the thin film solar cell.

The laser processing may be comprised of irradiating the desired silicon layer with a plurality of short laser pulses so as to uniformly improve the long wavelength quantum efficiency of the laser processed layer. In one embodiment, the laser pulses are at high enough energy to be above the melting threshold of the irradiated semiconductor. The number of laser pulses can vary from 1 per area to many hundreds per area so as to sufficiently alter the semiconductor surface to ensure increased quantum efficiency as compared to amorphous silicon at wavelengths longer than 750 nm. The process environment during laser irradiation can include a desired dopant gas or it may be an inert environment. The inert environment is preferred in the embodiment where the dopant species of the laser processed layer is included by chemical vapor deposition.

In one embodiment, a substrate comprised of a glass supporting substrate, a thin transparent conductive layer, a layer of thin p-doped silicon, and a layer of intrinsic silicon is prepared for laser processing. The intrinsic silicon layer is then irradiated with between 1 and 50 laser pulses of duration in between 20 fs (femtoseconds) and 750 fs and at a fluence between 1 kJ/m² and 6 kJ/m². The laser irradiation is carried out in an process environment that contains a preferred n-type dopant species (such as phosphorous, sulfur, etc.). During the laser processing the desired chemical dopant may be present in gas form, solid form on the surface of the semiconductor, liquid form on the surface of the semiconductor, or embedded/dissolved/deposited within the surface of the semiconductor. However, it can be understood by those skilled in the art that the laser process can also be performed to introduce a p-type dopant into a structure that is comprised of an n-type layer covered by an intrinsic silicon layer. In addition, the dopant species in the laser processed layer can be introduced into the semiconductor substrate prior to laser irradiation.

In some embodiments, the laser processed layer may be annealed in a gas flow oven, at various temperatures between 1000K and 1500K, with the temperature determined by design parameters and characteristics. The substrate including the laser processed layer may be heated to the annealing temperature and held for approximately ten minutes. In other embodiments, the required annealing time may be significantly more or less as required by the system and design constraints. During the anneal process, the gas flow in the oven may be held constant for the entire anneal process to prevent oxygen diffusion into the surface.

In some embodiments, a lower surface roughness of the laser processed layer may provide better photovoltaic performance. This result has been obtained through actual reduction to practice and the reasons for the improved performance may include that a lower surface roughness will provide a less torturous path for charge carriers to travel from the laser modified surface region to the top metal electrode of the solar cell. In addition, the top metal electrode will form a more uniform layer on a surface with lower surface roughness. In general, improved results can be obtained with a laser processed layer that includes resultant structures from the laser processing that are less than 10 microns, and specifically less than 3 microns in height from the laser modified surface.

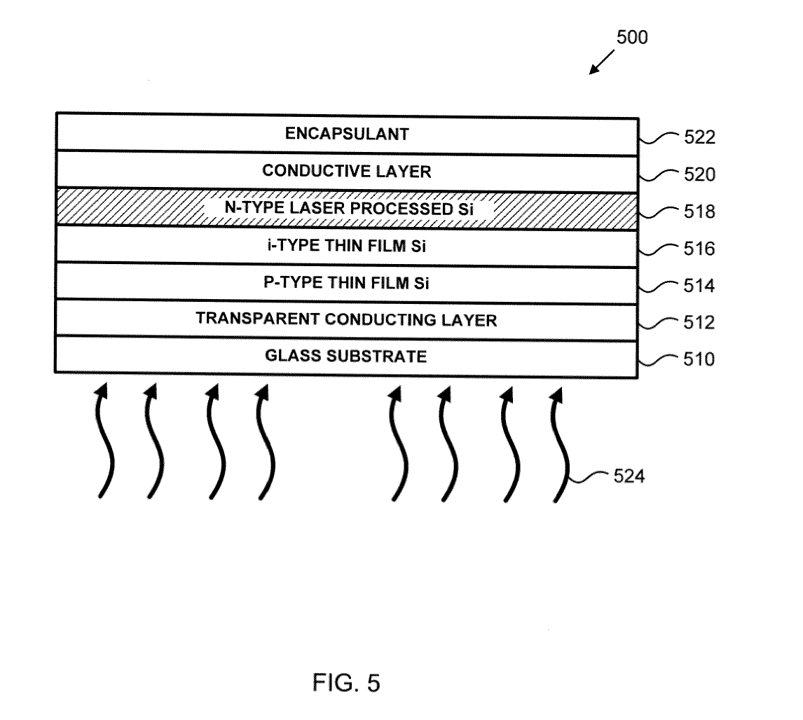

Referring to FIG. 5, a cross-section 500 of an exemplary solar cell including a laser processed silicon layer includes a structural substrate layer 510, a transparent conductive substrate layer 512, a p-type thin film silicon layer 514, an i-type thin film silicon layer 516, a n-type laser processed silicon layer 518, a conductive layer 520, and an encapsulant layer 522.

The structural substrate layer 510 may be comprised of a suitable transparent material such as a glass. The structural substrate layer 510 provides a base for the transparent conductive substrate layer 512. The conductive substrate layer 512 may be of any suitable material that is a transparent conductive layer (such as indium tin oxide). The p-type thin film silicon layer 514 is in contact with the top surface of the transparent conductive substrate layer 512, and may be of an appropriate thickness for a specific application, for example, between 1-5000 nm thick, particularly 5-500 nm. An intrinsic or i-type thin film silicon layer 516 of appropriate thickness, e.g. 0-5000 nm thick, particularly 500 to 1000 nm, resides on top of the p-type thin film silicon layer 514. In some embodiments, an i-type silicon layer may not be present. The top surface of the i-type thin film silicon layer 516 is in contact with the n-type laser processed silicon layer 518. The n-type laser processed silicon layer 518 is an appropriate thickness for the application, such as 10-5000 nm thick, particularly 100 to 500 nm. A conductive layer 520, resides on top of and is in contact with the n-type laser processed silicon layer 518. The encapsulant layer 522 may be on top of the conductive layer 520. In some embodiments, the total material thickness of the thin film solar cell may be less than 20 microns. The cross section 500 of the exemplary solar cell is oriented as it would be during the manufacturing process in which the top face of the solar cell which incident sunlight 524 strikes is facing down towards the floor. The incident sunlight 524 is shown in FIG. 5 striking the glass substrate layer 510 of the solar cell 500 (which in normal operation is directed upwards towards the sun). The various wavelengths of the sunlight 524 are absorbed by the layers 514, 516, and 518 of the solar cell 500.

The incident sunlight 524 includes relatively shorter wavelengths of light which are absorbed and converted into photocarriers within the p-type thin film silicon layer 514, or alternatively, the i-type thin film silicon layer 516. Longer wavelengths of incident sunlight 524 pass substantially unabsorbed through the first two silicon layers 514, 516. The longer wavelengths of light may be absorbed in the n-type laser processed silicon layer 518. Thus, the n-type laser processed silicon layer 518 may perform as a back-stop for longer wavelength light.

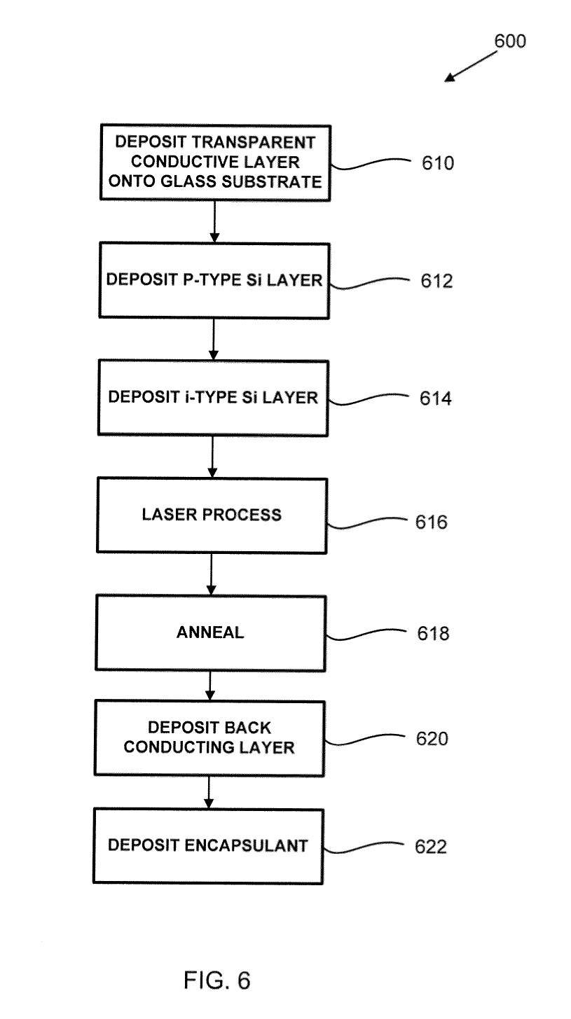

Referring to FIG. 6, with further reference to FIG. 5, various stages of a process 600 are shown for manufacturing a thin film solar cell including a laser processed silicon layer. The process 600 includes providing a thin film layer of silicon deposited onto a glass substrate covered with an appropriate transparent conductive layer 610, depositing a thin layer of amorphous silicon onto the conductive layer so that there is a layer of p-doped silicon 612 on top of the conductive layer and depositing an intrinsic layer 614 on top of the p-doped silicon layer. Directing an appropriately sized laser beam or curtain of laser light onto the intrinsic silicon in an automated manner as the silicon layer and conductive substrate are in an appropriate ambient environment to introduce n-type dopant during laser irradiation 616, annealing the processed silicon to activate the dopant species implanted during laser processing 618, depositing a conducting back contact layer such as aluminum 620 and depositing an encapsulant layer 622 on the back contact layer.

The process 600 is differentiated from the previously mentioned manufacturing process 400 described for flexible substrates not only by the different order of “laying down” or depositing the silicon layers, but also by the fact that a silicon deposition stage can be eliminated from the process by laser irradiating a portion of the intrinsic (i-type) silicon layer in the presence of a proper chemical dopant gas to create the desired third layer of either n-type or p-type doped silicon. This manufacturing process 600 may speed up and reduce the cost of thin film photovoltaic manufacturing. The intrinsic silicon layer may be deposited in an appropriately thicker layer if necessary to compensate for the portion of the intrinsic silicon layer that is irradiated to become a laser processed (n-type or p-type) layer such as the n-type laser processed layer 518 in FIG. 5.

The manufacturing process 600 may be configurable by a user for either a p-i-n, or a n-i-p solar cell architecture. Thus the first silicon layer deposition stage 612 may be configured to deposit a n-type doped layer, or as in the present embodiment, a p-type doped layer. The laser processed silicon layer generated by the laser process stage 616 may then be a n-type or p-type layer depending on the dopant species used during the laser processing stage 616. If the first silicon layer deposition stage 612 is configured to be n-type, then the laser process stage 616 generates a p-type silicon layer. In contrast, if the first silicon layer deposition stage 612 is of the p-type, then the laser process stage 616 generates a n-type silicon layer.

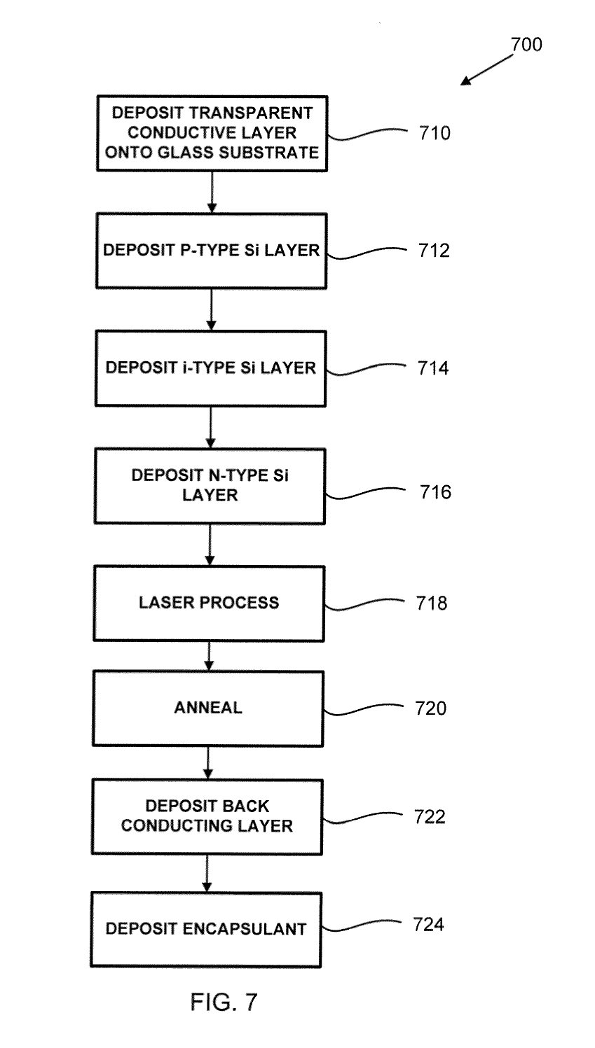

Referring to FIG. 7, in another embodiment, various stages of a process 700 are shown for manufacturing a thin film solar cell including a laser processed silicon layer. The process 700 includes providing a thin film layer of silicon deposited onto a glass substrate covered with an appropriate transparent conductive layer 710, depositing a thin layer of amorphous silicon onto the conductive layer so that there is a layer of p-doped silicon 712 on top of the conductive layer and an intrinsic layer 714 on top of the p-doped silicon layer and an n-doped layer approximately 500-1000 nm thick on top of the intrinsic layer 716. Directing an appropriately sized laser beam or curtain of laser light onto the n-doped layer of silicon in an automated manner as the silicon layer and conductive substrate are in an appropriate inert ambient environment 718, annealing the processed silicon 720, depositing a conducting back contact layer 722 such as aluminum and depositing an encapsulant layer 724 on the back contact layer.

The process 700 adds a third silicon deposition stage 716 as compared to the process 600 above. With the addition of the third deposition stage 716, the n-type (or p-type depending on configuration) silicon layer is pre-doped prior to the laser processing stage 718. Since the third silicon layer is pre-doped in the deposition stage 716, the laser processing stage 718 can be performed with an appropriate inert gas ambient environment. Performing the laser processing stage 718 with an inert gas environment may allow standardization of the laser processing equipment thereby reducing cost and complexity. In alternate embodiments, a silicon layer may be processed in a suitable reactive environment.

The manufacturing process 700 may be configurable by a user for either a p-i-n, or a n-i-p solar cell architecture. Thus the first silicon layer deposition stage 712 may be configured to deposit a n-type doped layer, or as in the present embodiment, a p-type doped layer. The third silicon deposition stage 716 may then be a n-type or p-type layer depending on the dopant species used during the first deposition stage 712. If the first silicon layer deposition stage 712 is configured to be n-type, then the third silicon deposition stage 716 deposits a p-type silicon layer. In contrast, if the first silicon layer deposition stage 712 is of the p-type, then the third silicon deposition stage 716 generates a n-type silicon layer.

As stated and described herein, the thin film systems and the method of manufacturing thereof produce a thin film system with greater quantum efficiencies. Quantum efficiency is often described as the number of electron hole pairs collected per photon in a solar cell. In particular, quantum efficiency measures the efficiency of light power that is converted to electric power. Quantum efficiency therefore relates to the response of a solar cell to the various wavelengths in the spectrum of light shining on the cell. The quantum efficiency may be given either as a function of wavelength or as energy. If all photons of a certain wavelength are absorbed and the resulting minority carriers are collected, then the quantum efficiency at that particular wavelength is unity. The quantum efficiency for photons with energy below the band gap is zero. The invention described herein achieves the following quantum efficiencies: quantum efficiencies greater than about 85% for wavelengths between about 700 nm and 1050 nm; quantum efficiencies greater than about 30% for wavelengths between about 700 nm and 1150 nm; quantum efficiencies greater than about 85% in one wavelength between about 900 nm and 1100 nm; quantum efficiencies greater than about 90% in one wavelength beyond about 700 nm for a thin film; quantum efficiencies greater than about 80% in one wavelength beyond about 900 nm for a thin film of silicon. In some embodiments, a thin film solar cell may be provided with quantum efficiency greater than 90%. In some embodiments, high quantum efficiencies may be achieved for light wavelengths from about 1100 nm to 2500 nm.

These high quantum efficiencies are made possible because the laser process arranges the dopant species and crystalline structure in a unique way that enables very high absorption coefficients at longer wavelengths while not limiting the carrier lifetime. The carrier lifetime may often be described as the average time it takes an excess minority carrier to recombine. The combination of high absorption and long carrier lifetime results in the efficient creation of electron-hole pairs in a very thin layer of silicon with light of wavelength longer than 700 nm. The electron-hole pairs are then collected efficiently because of sufficient carrier lifetime in the thin absorption layer.

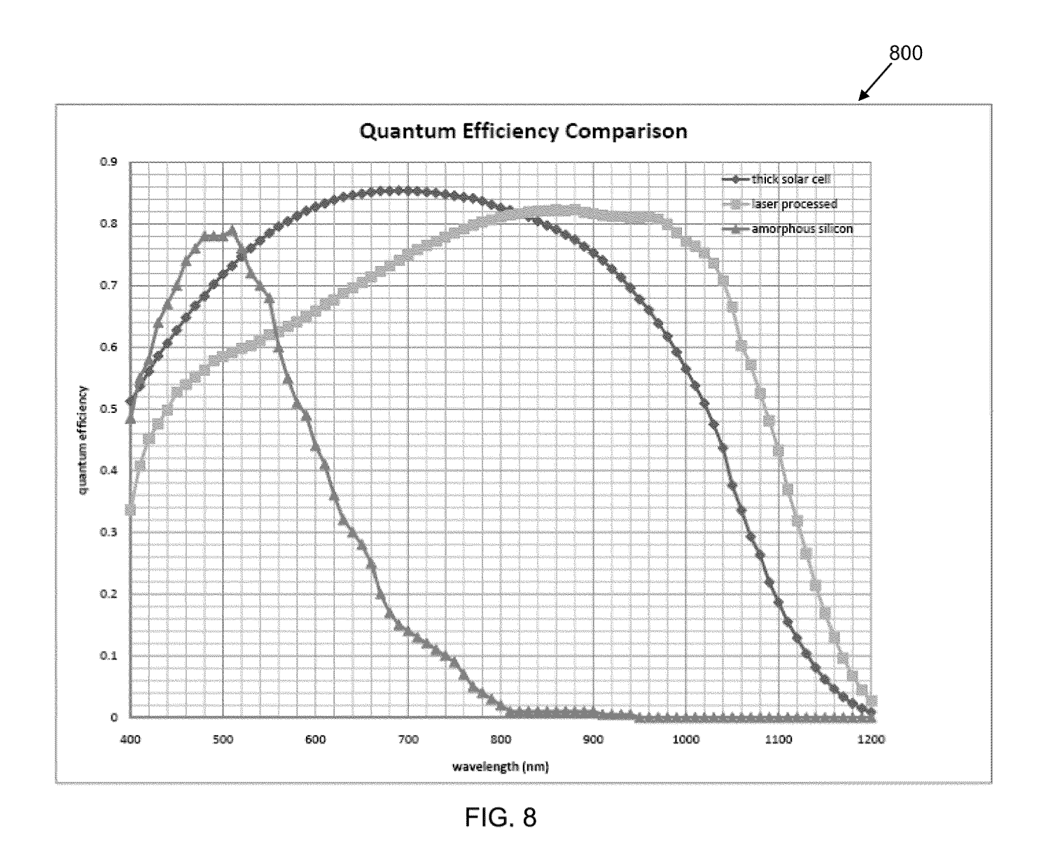

Referring to FIG. 8, quantum efficiency curves are plotted for three exemplary photovoltaic devices. The plotted devices are a typical amorphous silicon solar cell, a typical high efficiency monocrystalline solar cell, and a short pulse laser processed silicon solar cell as disclosed herein. The quantum efficiencies for the devices is plotted as a function of the wavelength of incident light. The laser processed solar cell has significantly increased quantum efficiency as compared to the amorphous silicon solar cell for wavelengths longer than 700 nm and has increased quantum efficiency as compared to a high efficiency monocrystalline solar cell for wavelengths longer than 800 nm.

The present invention should not be considered limited to the particular embodiments described above, but rather should be understood to cover all aspects of the invention as fairly set out in the attached claims. Various modifications, equivalent processes, as well as numerous structures to which the present invention may be applicable, will be readily apparent to those skilled in the art to which the present invention is directed upon review of the present disclosure. The claims are intended to cover such modifications.

What is claimed is:

1. An article of manufacture arranged and manufactured to comprise:
a substrate layer;
a thin film solar cell disposed on the substrate layer, said thin film solar cell comprising a laser-treated portion, the laser treated-portion being formed by application of laser radiation in an automated process.

2. The article of claim 1, wherein the substrate layer is flexible.

3. The article of claim 1, the laser radiation comprising pulsed laser radiation.

4. The article of claim 1, wherein the application of the laser is performed in an inert environment.

5. The article of claim 1, wherein the application of the laser is performed in a process environment that contains a desired dopant chemical species.

6. The article of claim 1, wherein the thin film solar cell comprises an intrinsic silicon layer.

7. The article of claim 1, wherein the application of laser radiation is applied to the intrinsic layer.

8. The article of claim 1, wherein the application of laser radiation in an automated process is controlled by a computer.

9. The article of claim 1, wherein the thin film solar cell is a solar cell with quantum efficiency greater than 50% for light wavelengths longer than 800 nanometers and the thin film solar cell has a material thickness less than 20 microns.

10. The article of claim 1, wherein the thin film solar cell is a solar cell with quantum efficiency greater than 80% for light wavelengths longer than 900 nanometers and the thin film solar cell has a material thickness less than 20 microns.

11. The article of claim 3, wherein the application of the pulsed laser radiation further includes annealing the laser-treated portion at an anneal temperature greater than 1075 K and less than 1475 K, and application of the pulsed laser radiation is performed with less than 100 laser shots per unit area and a laser fluence greater than 1 kJ/m² and less than 6 kJ/m².

12. The article of claim 1, wherein the laser-treated portion includes resultant surface structures from the laser treatment that are less than 10 microns high from the laser-treated portion surface.

13. The article of claim 1, wherein the laser-treated portion includes resultant surface structures from the laser treatment that are less than 5 microns high from the laser-treated portion surface.

14. The article of claim 1, wherein the laser-treated portion includes resultant surface structures from the laser treatment that are less than 3 microns high from the laser-treated portion surface.

15. A method for automated manufacturing of thin film solar cells including a laser processed layer, the method comprising:
depositing a plurality of substantially planar layers in proximity with one another, including at least a first semiconductor layer;
feeding said plurality of layers through a plurality of processing steps;
irradiating at least a portion of a layer of said plurality of layers with a source of laser radiation; and
using a control computer to control at least one of said acts of feeding and irradiating in said automated manufacture of said thin film solar cells.

16. The method of claim 15, wherein the depositing of a plurality of substantially planar layers includes depositing a second semiconductor layer, the second semiconductor layer being deposited subsequent to the irradiating of the first semiconductor layer.

17. The method of claim 16, wherein the depositing of a plurality of substantially planar layers includes depositing a third semiconductor layer, the third semiconductor layer being deposited subsequent to the deposition of the second semiconductor layer.

18. The method of claim 15, wherein the depositing of a plurality of substantially planar layers includes depositing a second semiconductor layer, and irradiating said second semiconductor layer with said pulsed source of radiation.

19. The method of claim 15, wherein the depositing of a plurality of substantially planar layers includes depositing a second semiconductor layer, and depositing a third semiconductor layer, and the irradiating includes irradiating the third semiconductor layer with a pulsed source of radiation.

20. The method of claim 19, wherein the irradiation of the third semiconductor layer is performed in an inert gas environment.

21. The method of claim 15, further comprising providing a flexible substrate for depositing said plurality of substantially planar layers onto the flexible substrate using a roll-to-roll process.

22. The method of claim 15, wherein the irradiating comprises irradiating with femtosecond pulsed laser radiation.

23. The method of claim 15, wherein the irradiation of a semiconductor layer is performed in a gas environment that contains a desired dopant chemical species.

24. The method of claim 15, further comprising providing a substantially transparent substrate for depositing a plurality of substantially planar layers onto in an automated process.

25. The method of claim 15, wherein the automated manufacture of said thin film solar cells produces a solar cell with quantum efficiency greater than 50% for light wavelengths longer than 800 nanometers and the thin film solar cell has a material thickness less than 20 microns.

26. The method of claim 15, wherein the automated manufacture of said thin film solar cells produces a solar cell with quantum efficiency greater than 80% for light wavelengths longer than 900 nanometers and the thin film solar cell has a material thickness less than 20 microns.

27. The method of claim 15, wherein the irradiation of the at least a portion of a layer further includes annealing the treated portion at an anneal temperature greater than 1075 K and less than 1475 K, and application of the radiation is performed with a pulsed laser with less than 100 laser shots per unit area and a laser fluence greater than 1 kJ/m² and less than 6 kJ/m².

28. The method of claim 15, wherein the radiation treated portion includes resultant surface structures from the irradiation that are less than 10 microns high from the treated portion surface.

29. The method of claim 15, wherein the radiation treated portion includes resultant surface structures from the irradiation that are less than 5 microns high from the treated portion surface.

30. The method of claim 15, wherein the radiation treated portion includes resultant surface structures from the irradiation that are less than 3 microns high from the treated portion surface.

31. An article of manufacture arranged and manufactured to comprise:
a substrate layer; and
a thin film solar cell disposed on the substrate layer, said thin film solar cell comprising a laser-treated portion, the laser treated-portion being formed by application of laser radiation, wherein the thin film solar cell comprises a solar cell with quantum efficiency greater than 80% for light wavelengths longer than 900 nanometers and the thin film solar cell has a material thickness less than 20 microns.

32. The article of claim 31 wherein said quantum efficiency is in the range of 80% to 90%.

33. The article of claim 31 wherein said quantum efficiency is greater than 90%.

34. The article of claim 31 wherein said light wavelengths are in the range of 900 to 1100 nanometers.

35. The article of claim 31 wherein said light wavelengths are in the range of 1100 to 2500 nanometers.

36. The article of claim 31 wherein the laser-treated portion has a material thickness less than 1 micron.
